(19) United States
(12) Patent Application Publication
(10) Pub. No.: US 2024/0397821 A1
(43) Pub. Date: Nov. 28, 2024

(54) ORGANIC LIGHT-EMITTING COMPOUND AND ORGANIC ELECTROLUMINESCENT DEVICE USING SAME

(71) Applicant: SOLUS ADVANCED MATERIALS CO., LTD., Iksan (KR)

(72) Inventors: Choonghahn KIM, Yongin (KR); Hwangyu SHIN, Yongin (KR)

(21) Appl. No.: 18/694,992

(22) PCT Filed: Dec. 30, 2022
(86) PCT No.: PCT/KR2022/021698

§ 371 Date: Mar. 25, 2024

(30) Foreign Application Priority Data
Dec. 30, 2021 (KR) 10-2021-0192140

(51) Int. Cl. H10K 85/60; C07F 5/02; C09K 11/06; H10K 50/12; H10K 101/20

(52) U.S. Cl. CPC H10K 85/658; C07F 5/027; C09K 11/06; C09K 2211/1018; H10K 50/12; H10K 2101/20

(57) ABSTRACT

Disclosed are a novel compound excellent in luminescence performance, and an organic electroluminescence device including the same in one or more organic material layers and improved in properties such as luminescence efficiency, driving voltage, and lifespan.

### TECHNICAL FIELD

The disclosure relates to a novel organic compound, which can be used as a material for an organic electroluminescence device, and an organic electroluminescence device including the same.

### BACKGROUND ART

An organic electroluminescence display has recently been actively developed as an image display device. Unlike a liquid crystal display or the like, the organic electroluminescence display is a so-called self-luminous display device that recombines holes and electrons injected from a first electrode and a second electrode in an emission layer so that a light emitting material containing an organic compound in the emission layer can emit light, thereby realizing a display.

To apply an organic electroluminescence device to the display, the organic electroluminescence device is required to have lower driving voltage, higher luminescence efficiency, and longer lifespan, and materials for reliably implementing such requirements of the organic electroluminescence device are continuously being developed.

In particular, recently, to implement high-efficiency organic electroluminescence devices, technologies are being developed for phosphorescence emission using triplet state energy or delayed fluorescence emission using a phenomenon where singlet excitons are generated by the collision of triplet excitons (triplet-triplet annihilation, TTA), and thermally activated delayed fluorescence (TADF) materials using a delayed fluorescence phenomenon are being developed.

### DISCLOSURE

### Technical Problem

An aspect of the disclosure is to provide a long-lifespan and high-efficiency organic electroluminescence device and a compound used therein.

Another aspect of the disclosure is to provide an organic electroluminescence device containing a thermally activated delayed fluorescence light-emitting material, and a compound used as the thermally activated delayed fluorescence light-emitting material.

### Technical Solution

According to an embodiment of the disclosure, there is provided a compound represented by the following Chemical formula 1.

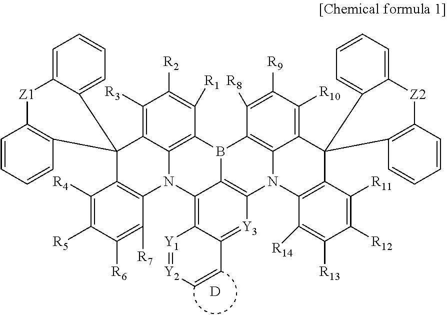

In the Chemical formula 1,
R₁ to R₁₄ are each independently selected from a group consisting of a C₁ to C₃₀ alkyl group, a C₃ to C₃₀ cycloalkyl group, a C₁ to C₆₀ alkoxy group, a C₁ to C₆₀ thioalkoxy group, a carbonyl group, a carboxyl group, a nitro group, a cyano group, an amine group, a C₆ to C₃₀ arylamine group, a C₃ to C₃₀ heteroaryl group, a C₅ to C₆₀ monocyclic aryl group, a C₆ to C₆₀ condensed ring aryl group, a C₆ to C₆₀ aryloxy group, a C₅ to C₆₀ monocyclic heteroaryl group, and a C₅ to C₆₀ condensed ring heteroaryl group, and are bonded to an adjacent group to form a condensed ring,
Y₁ to Y₃ are each be independently selected from a group consisting of N or C(R₁₅) (R₁₆), at least one of which is N,
R₁₅ and R₁₆ are each independently selected from a group consisting of hydrogen, a C₁ to C₁₀ alkyl group, a C₃ to C₁₀ cycloalkyl group, a C₁ to C₁₀ alkoxy group, a halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₅ and R₁₆ are bonded to each other or bonded to an adjacent group to form a condensed ring,
Z₁ and Z₂ are each independently selected from a group consisting of C(R₁₇)(R₁₈), Si(R₁₇)(R₁₈), N(R₁₇), O or S,
R₁₇ and R₁₈ are each independently selected from a group consisting of hydrogen, a C₁ to C₁₀ alkyl group, a C₃ to C₁₀ cycloalkyl group, a C₁ to C₁₀ alkoxy group, halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₇ and R₁₈ are bonded to each other or are bonded to an adjacent group to form a condensed ring,
a ring D is a group fused to a 6-membered ring structure containing Y₁ and Y₂, and is selected from a group consisting of a C₆-C₆₀ monocyclic aryl group, a C₆-C₆₀ condensed ring aryl group, a C₆-C₆₀ aryloxy group, a C₅ to C₆₀ monocyclic heteroaryl group, and a C₅ to C₆₀ condensed ring heteroaryl group, and
the alkyl group, the cycloalkyl group, the alkoxy group, the thioalkoxy group, the arylamine group, the heteroaryl group, the monocyclic aryl group, the condensed ring aryl group, the aryloxy group, the monocyclic heteroaryl group or the fused heteroaryl group are unsubstituted or substituted with one or more substituents each independently selected from a group consisting of heavy hydrogen, halogen, a cyano group, a nitro group, a C₁ to C₄₀ alkyl group, a C₂ to C₄₀ alkenyl group, a C₂ to C₄₀ alkynyl group, a C₆ to C₆₀ aryl group, a heteroaryl group having 5 to 60 nuclear atoms, a C₆ to C₆₀ aryloxy group, a C₁ to C₄₀ alkyloxy group, a C₆ to C₆₀ arylamine group, a C₃ to C₄₀ cycloalkyl group, a heterocycloalkyl group having 3 to 40 nuclear atoms, a C₁ to C₄₀ alkylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylsilyl group, which are the same as or different from each other when substituted with a plurality of substituents.

According to another embodiment of the disclosure, there is provided an organic electroluminescence device including: a first electrode; a hole transport region disposed on the first electrode; an emission layer disposed on the hole transport region; an electron transport region disposed on the emission layer; and a second electrode disposed on the electron transport region, wherein the emission layer contains the compound represented by the foregoing Chemical formula 1.

For reference, the “alkyl” used herein refers to a monovalent substituent derived from a linear or branched saturated hydrocarbon. As an example, the alkyl may be, but is not limited to, methyl, ethyl, propyl, isobutyl, sec-butyl, pentyl, iso-amyl or hexyl.

The “alkenyl” used herein refers to a monovalent substituent derived from a linear or branched unsaturated hydrocarbon having 2 to 40 carbon atoms and one or more carbon-carbon double bonds. As an example, the alkenyl may be, but is not limited to, vinyl, allyl, isopropenyl or 2-butenyl.

The “alkynyl” used herein refers to a monovalent substituent derived from a linear or branched unsaturated hydrocarbon having one or more carbon-carbon triple bonds. As an example, the alkynyl may be, but is not limited to, ethynyl or 2-propynyl.

The “aryl” used herein refers to a monovalent substituent derived from an aromatic hydrocarbon having a single ring or a combination of two or more rings. In addition, the aryl may be a monovalent substituent that has 2 or more rings condensed with each other, only carbon atoms as a ring-forming atom (e.g., having 8 to 60 carbon atoms), and non-aromaticity in the entire molecular structure. As an example, the aryl may be, but is not limited to, phenyl, naphthyl, phenanthryl, anthryl or fluorenyl.

The “heteroaryl” used herein refers to a monovalent substituent derived from a monoheterocyclic or polyheterocyclic aromatic hydrocarbon. Here, one or more, preferably, 1 to 3 carbon atoms of the ring are substituted with heteroatoms selected among N, O, P, S and Se. In addition, the heteroaryl may be a monovalent group having 2 or more rings simply pendant to or condensed with each other, heteroatoms selected among N, O, P, S and Se as a ring-forming atom, and non-aromaticity in the entire molecular structure. An example of the heteroaryl may be, but is not limited to, a 6-membered monocyclic ring such as pyridyl, pyrazinyl, pyrimidinyl, pyridazinyl or triazinyl, a polycyclic ring such as phenoxathienyl, indolizinyl, indolyl, purinyl, quinolyl, benzothiazole or carbazolyl, 2-furanyl, N-imidazolyl, 2-isoxazolyl, 2-pyridinyl, or 2-pyrimidinyl.

The “aryloxy” used herein refers to a monovalent substituent represented by RO—, in which R represents an aryl. An example of the aryloxy may be, but is not limited to, phenyloxy, naphthyloxy, or diphenyloxy.

The “alkoxy” or “alkyloxy” used herein refers to a monovalent substituent represented by R′O—, in which R′ represents an alkyl, and may include a linear, branched or cyclic structure. An example of the alkyloxy may be, but is not limited to, methoxy, ethoxy, n-propoxy, 1-propoxy, t-butoxy, n-butoxy, or pentoxy.

In the disclosure, the number of carbon atoms of the amine group is not particularly limited, but is preferably 1 to 30. The amine group may include the alkylamine group and the arylamine group. An example of the amine group may be, but is not limited to, a methylamine group, a dimethylamine group, a phenylamine group, a naphthylamine group, a 9-methyl-anthracenylamine group, or a triphenylamine group.

The “arylamine” used herein refers to an amine substituted with an aryl.

The “cycloalkyl” used herein refers to a monovalent substituent derived from a monocyclic or polycyclic non-aromatic hydrocarbon. An example of the cycloalkyl may be, but is not limited to, cyclopropyl, cyclopentyl, cyclohexyl, norbornyl, or adamantine.

The “heterocycloalkyl” used herein refers to a monovalent substituent derived from a non-aromatic hydrocarbon, and one or more carbons, preferably, 1 to 3 carbon atoms of the ring are substituted with heteroatoms such as N, O, S or Se. An example of the heterocycloalkyl may be, but is not limited to, morpholine or piperazine.

The “alkylsilyl” used herein refers to silyl substituted with alkyl, and the “arylsilyl” used herein refers to silyl substituted with an aryl.

The “condensed ring” used herein refers to a condensed aliphatic ring, a condensed aromatic ring, a condensed heteroaliphatic ring, a condensed heteroaromatic ring or a combination thereof.

In the disclosure, the term “substituted or unsubstituted” means being substituted with one or more substituents selected from the group consisting of heavy hydrogen atoms, halogen atoms, a cyano group, a nitro group, an amine group, a silyl group, a boron group, a phosphine oxide group, a phosphine sulfide group, an alkyl group, an alkenyl group, a aryl group, and a hetero ring group.

Further, each of the substituents given as above may be substituted or unsubstituted.

### Advantageous Effects

An organic electroluminescence device according to an embodiment of the disclosure can have a high efficiency and a long lifespan.

A compound according to an embodiment of the disclosure can improve the lifespan and efficiency of an organic electroluminescence device.

### DESCRIPTION OF DRAWINGS

### Mode for Invention

Hereinafter, the disclosure will be described in detail.

### 1. Novel Organic Compound

The disclosure may be modified in various ways and may have various embodiments, and thus specific embodiments will be illustrated in the accompanying drawings and described in detail. However, it should be understood that the disclosure is not intended to be limited to the specific embodiments but includes all modifications, equivalents and substitutions which fall within the spirit and technological scope of the disclosure.

According to an embodiment, an emission layer (EML) contains a compound represented by Chemical formula 1.

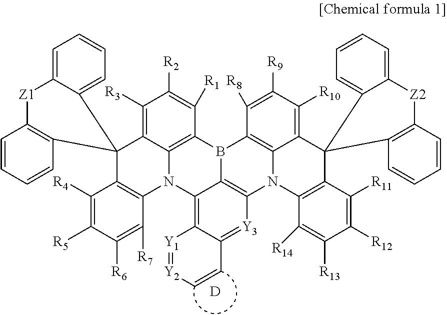

In the Chemical formula 1,
R₁ to R₁₄ are each independently selected from a group consisting of a C₁ to C₃₀ alkyl group, a C₃ to C₃₀ cycloalkyl group, a C₁ to C₆₀ alkoxy group, a C₁ to C₁₀ thioalkoxy group, a carbonyl group, a carboxyl group, a nitro group, a cyano group, an amine group, a C₆ to C₃₀ arylamine group, a C₃ to C₃₀ heteroaryl group, a C₅ to C₆₀ monocyclic aryl group, a C₆ to C₆₀ condensed ring aryl group, a C₆ to C₆₀ aryloxy group, a C₅ to C₆₀ monocyclic heteroaryl group, and a C₅ to C₆₀ condensed ring heteroaryl group, and are bonded to an adjacent group to form a condensed ring,
Y₁ to Y₃ are each be independently selected from a group consisting of N or C(R₁₅)(R₁₆), at least one of which is N,
R₁₅ and R₁₆ are each independently selected from a group consisting of hydrogen, a C₁ to C₁₀ alkyl group, a C₃ to C₁₀ cycloalkyl group, a C₁ to C₁₀ alkoxy group, a halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₅ and R₁₆ are bonded to each other or bonded to an adjacent group to form a condensed ring,
Z₁ and Z₂ are each independently selected from a group consisting of C(R₁₇)(R₁₈), Si(R₁₇)(R₁₈), N(R₁₇), O or S,
R₁₇ and R₁₈ are each independently selected from a group consisting of hydrogen, a C₁ to C₁₀ alkyl group, a C₃ to C₁₀ cycloalkyl group, a C₁ to C₁₀ alkoxy group, halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₇ and R₁₈ are bonded to each other or are bonded to an adjacent group to form a condensed ring,
a ring D is a group fused to a 6-membered ring structure containing Y₁ and Y₂, and is selected from a group consisting of a C₆-C₆₀ monocyclic aryl group, a C₆-C₆₀ condensed ring aryl group, a C₆-C₆₀ aryloxy group, a C₅ to C₆₀ monocyclic heteroaryl group, and a C₅ to C₆₀ condensed ring heteroaryl group, and
the alkyl group, the cycloalkyl group, the alkoxy group, the thioalkoxy group, the arylamine group, the heteroaryl group, the monocyclic aryl group, the condensed ring aryl group, the aryloxy group, the monocyclic heteroaryl group or the fused heteroaryl group are unsubstituted or substituted with one or more substituents each independently selected from a group consisting of heavy hydrogen, halogen, a cyano group, a nitro group, a C₁ to C₄₀ alkyl group, a C₂ to C₄₀ alkenyl group, a C₂ to C₄₀ alkynyl group, a C₆ to C₆₀ aryl group, a heteroaryl group having 5 to 60 nuclear atoms, a C₆ to C₆₀ aryloxy group, a C₁ to C₄₀ alkyloxy group, a C₆ to C₆₀ arylamine group, a C₃ to C₄₀ cycloalkyl group, a heterocycloalkyl group having 3 to 40 nuclear atoms, a C₁ to C₄₀ alkylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylsilyl group, which are the same as or different from each other when substituted with a plurality of substituents.

The ring D may be represented by the following Chemical formula 2 or Chemical formula 3.

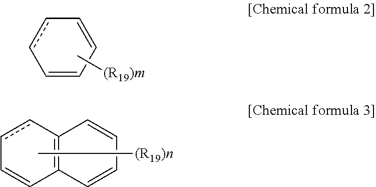

In the Chemical formulae 2 and 3,
the dotted line means a part that is fused;
m is an integer ranging from 0 to 4;
n is an integer ranging from 0 to 6;
R₁₉ is selected from a group consisting of hydrogen, heavy hydrogen, halogen, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₃ to C₄₀ alkylsilyl group, a C₆ to C₆₀ arylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylamine group, which are the same as or different from each other when the R₁₃ is present in plural number; and

the alkyl group, alkenyl group, alkynyl group, aryl group, heteroaryl group, aryloxy group, alkyloxy group, cycloalkyl group, heterocycloalkyl group, arylamine group, alkylsilyl group, alkyl boron group, aryl boron group, arylphosphanyl group, mono or diarylphosphinyl group, and arylsilyl group of the R₁₉ are unsubstituted or substituted with one or more substituents each independently selected from a group consisting of heavy hydrogen, halogen, a cyano group, a nitro group, a C₁ to C₄₀ alkyl group, a C₂ to C₄₀ alkenyl group, a C₂ to C₄₀ alkynyl group, a C₆ to Coo aryl group, a heteroaryl group having 5 to 60 nuclear atoms, a C₆ to C₆₀ aryloxy group, a C₁ to C₄₀ alkyloxy group, a C₆ to C₆₀ arylamine group, a C₃ to C₄₀ cycloalkyl group, a heterocycloalkyl group having 3 to 40 nuclear atoms, a C₁ to C₄₀ alkylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylsilyl group, which are the same as or different from each other when substituted with a plurality of substituents.

The compound according to an embodiment of the disclosure may be selected from a group consisting of the following compounds.

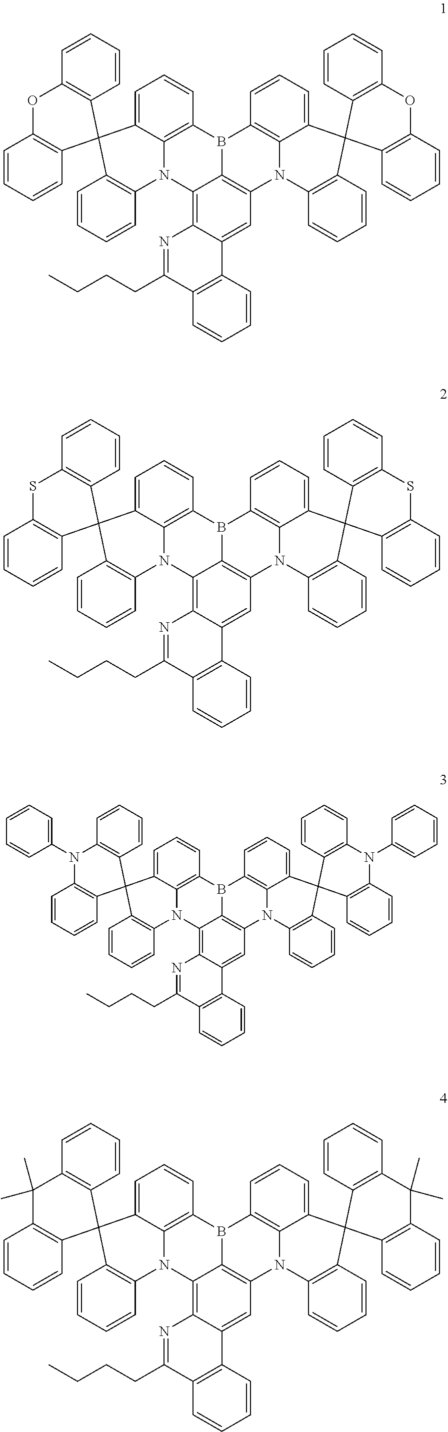

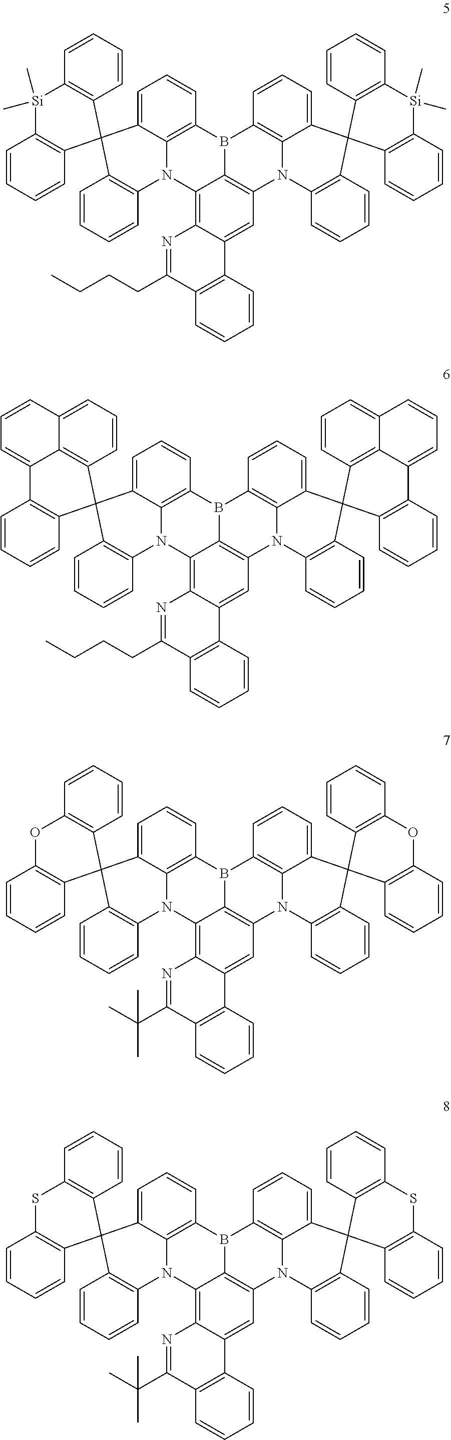

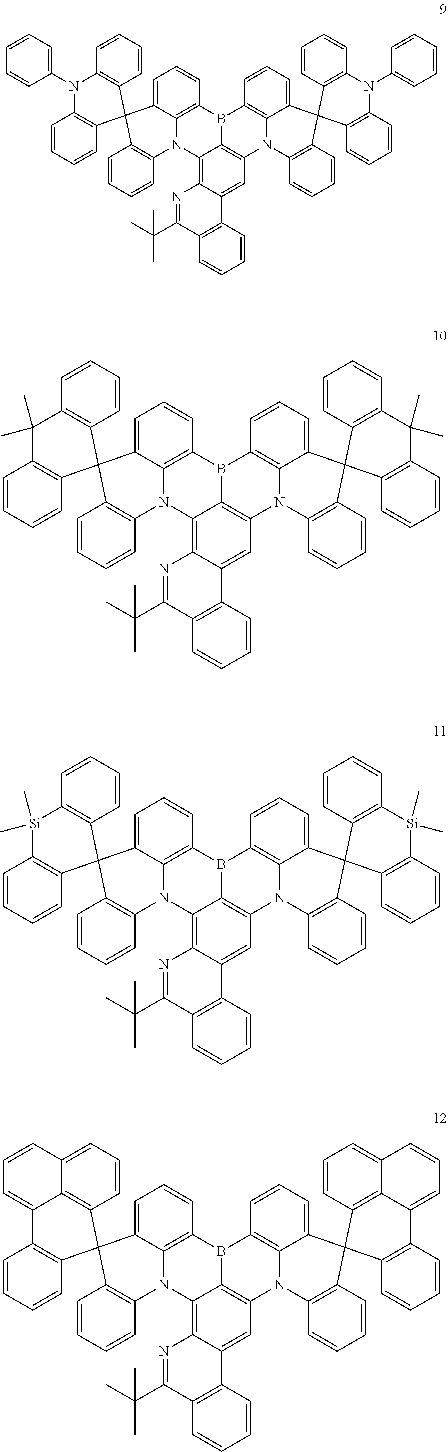

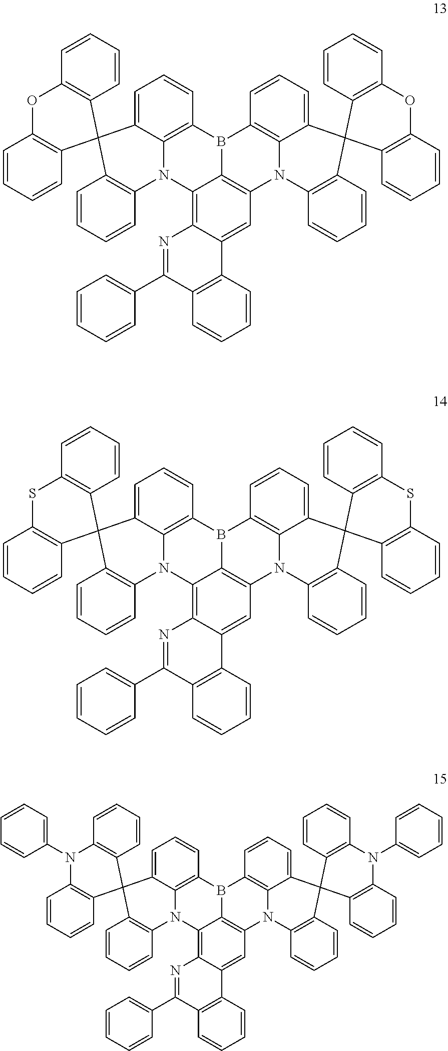 [SMILES: c1ccc(-c2nc3c4c5c(cc3c3ccccc23)N2c3ccccc3C3(c6ccccc6Oc6ccccc63)c3cccc(c32)B5c2cccc3c2N4c2ccccc2C32c3ccccc3Oc3ccccc32)cc1 ; c1ccc(-c2nc3c4c5c(cc3c3ccccc23)N2c3ccccc3C3(c6ccccc6Sc6ccccc63)c3cccc(c32)B5c2cccc3c2N4c2ccccc2C32c3ccccc3Sc3ccccc32)cc1 ; c1ccc(-c2nc3c4c5c(cc3c3ccccc23)N2c3ccccc3C3(c6ccccc6N(c6ccccc6)c6ccccc63)c3cccc(c32)B5c2cccc3c2N4c2ccccc2C32c3ccccc3N(c3ccccc3)c3ccccc32)cc1]

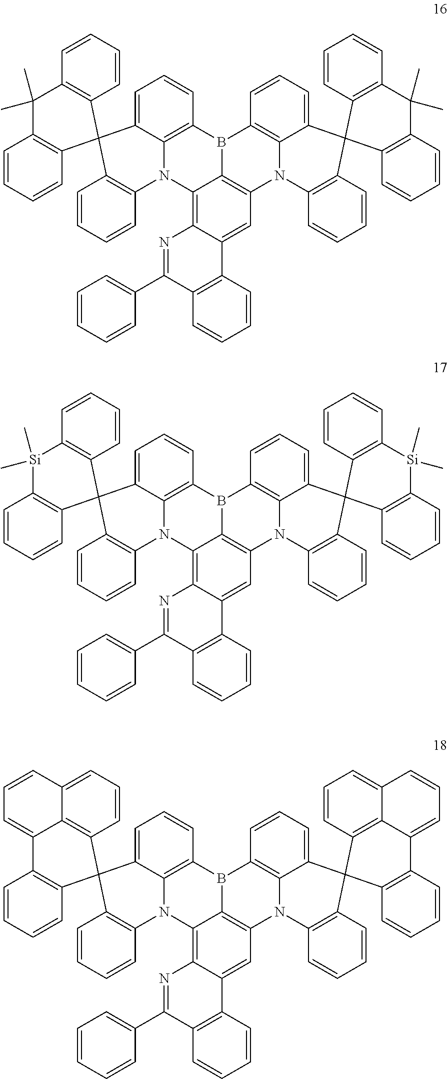

### 2. Organic Electroluminescence Device

Below, an organic electroluminescence device according to an embodiment of the disclosure will be described.

The organic electroluminescence device according to an embodiment may include a first electrode (EL1), a hole transport region (HTR), an emission layer (EML), an electron transport region (ETR), and a second electrode (EL2), which are stacked in sequence. The first electrode (EL1) and the second electrode (EL2) are disposed to face each other, and a plurality of organic layers may be disposed between the first electrode (EL1) and the second electrode (EL2). The plurality of organic layers may include the hole transport region (HTR), the emission layer (EML), and the electron transport region (ETR). In the organic electroluminescence device according to an embodiment, the emission layer (EML) may contain the foregoing compound according to an embodiment of the disclosure.

In the organic electroluminescence device according to an embodiment, the first electrode (EL1) has conductivity. The first electrode (EL1) may be formed of a metal alloy or a conductive compound. The first electrode (EL1) may be an anode. The first electrode (EL1) may be a transmissive electrode, a semi-transmissive electrode or a reflective electrode. When the first electrode (EL1) is the transmissive electrode, the first electrode (EL1) may contain transparent metal oxide, for example, indium tin oxide (ITO), indium zinc oxide (IZO), zinc oxide (ZnO), indium tin zinc oxide (ITZO), etc. When the first electrode (EL1) is the semi-transmissive electrode or the reflective electrode, the first electrode (EL1) may contain Ag, Mg, a Cu, Al, Pt, Pd, Au, Ni, Nd, Ir, a Cr, Li, a Ca, LiF/Ca, LiF/Al, Mo, Ti or a compound or mixture thereof (e.g., a mixture of Ag and Mg). Alternatively, the first electrode (EL1) may be structured to have a plurality of layers that includes a reflective layer or semi-transmissive layer formed of the foregoing materials, or the transparent conductive layer formed of ITO, IZO, ZnO, ITZO, etc. For example, the first electrode (EL1) may include a plurality of layers of ITO/Ag/ITO.

The hole transport region (HTR) is provided on the first electrode (EL1). The hole transport region (HTR) may include at least one of a hole injection layer (HIL), a hole transport layer (HTL), a hole buffer layer, and an electron blocking layer (EBL). The hole transport region (HTR) may have a single layer made of a single material, a single layer made of a plurality of different materials, or a multi-layered structure having a plurality of layers made of a plurality of different materials.

For example, the hole transport region (HTR) may have a single-layered structure of the hole injection layer (HIL) or the hole transport layer (HTL), or may have a single-layered structure made of a hole injection material and a hole transport material. Further, the hole transport region (HTR) may have a single-layered structure made of a plurality of different materials, or may have a structure of the hole injection layer (HIL)/hole transport layer (HTL), the hole injection layer (HIL)/hole transport layer (HTL)/the hole buffer layer, the hole injection layer (HIL)/hole buffer layer, the hole transport layer (HTL)/hole buffer layer, or the hole injection layer (HIL)/hole transport layer (HTL)/electron blocking layer (EBL), which are stacked in sequence from the first electrode (EL1), but an embodiment is not limited thereto.

The hole transport region (HTR) may be formed by various methods such as vacuum deposition, spin coating, casting, Langmuir-Blodgett (LB), inkjet printing, laser printing, and laser induced thermal imaging (LITI).

In the organic electroluminescence device according to an embodiment, the hole injection layer (HIL) may contain well-known hole injection materials. For example, the hole injection layer (HIL) may contain triphenylamine-containing polyetherketone (TPAPEK), 4-isopropyl-4′-methyldiphenyliodoniumtetrakis(pentafluorophenyl) borate (PPBI), N, N′-diphenyl-N, N′-bis-[4-(phenyl-m-tolyl-amino)-phenyl]-phenyl-4, 4′-diamine (DNTPD), copper phthalocyanine or the like phthalocyanine compound, 4,4′, 4″-tris(3-methyl phenyl phenylamino)triphenylamine (m-MTDATA), N, N′-di(1-naphthyl)-N,N′-diphenylbenzidine (NPB), N,N′-bis(1-naphthyl)-N,N′-diphenyl-4,4′-diamine (α-NPD), 4,4′,4″-tris {N,N diphenyl amino} triphenylamine (TDATA), 4,4′,4″-tris(N,N-2-naphthyl phenylamino)triphenylamine (2-TNATA), polyaniline/dodecyl benzene sulfonic acid (PANI/DBSA), poly(3,4-ethylenedioxythiophene)/poly(4-styrenesulfonate) (PEDOT/PSS), polyaniline/camphorsulfonic acid (PANI/CSA), polyaniline/poly(4-styrenesulfonate) (PANI/PSS), or HAT-CN (dipyrazino[2,3-f: 2′,3′-h]quinoxaline-2,3,6,7,10,11-hexacarbonitrile), etc. However, an embodiment is not limited thereto.

In the organic electroluminescence device according to an embodiment, the hole transport layer (HTL) may contain well-known hole transport materials. For example, the hole transport layer (HTL) may contain 1,1-bis[(di-4-trilamino)phenyl] cyclohexane (TAPC), N-phenylcarbazole, polyvinyl carbazole or the like carbazole derivatives, N,N′-bis(3-methylphenyl)-N,N′-diphenyl-[1,1-biphenyl]-4,4′-diamine (TPD), 4,4′,4″-tris(N-carbazolyl)triphenylamine (TCTA), or N,N′-di(1-naphthyl)-N,N′-diphenylbenzidine (NPB), N,N′-bis(1-naphthyl)-N,N′-diphenyl-4,4′-diamine (α-NPD), etc. However, an embodiment is not limited thereto. Meanwhile, the hole transport region (HTR) may further include the electron blocking layer (EBL), and the electron blocking layer (EBL) may be disposed between the hole transport layer (HTL) and the emission layer (EML). The electron blocking layer (EBL) is a layer that serves to prevent the injection of the electrons from the electron transport region (ETR) to the hole transport region (HTR).

The electron blocking layer (EBL) may contain general materials known in the art. The electron blocking layer (EBL) may for example contain N-phenylcarbazole, polyvinylcarbazole or the like carbazole-based derivatives, fluorine-based derivatives, TPD (N,N′-bis(3-methylphenyl)-N,N′-diphenyl-[1,1-biphenyl]-4,4′-diamine), TCTA(4,4′,4″-tris(Ncarbazolyl)triphenylamine) or the like triphenylamine-based derivatives, NPD (N,N′-di(naphthalene-1-yl)-N,N′-diplienyl-benzidine), TAPC(4,4′-Cyclohexylidene bis[N,N-bis(4-methylphenyl)benzenamine]), HMTPD(4,4′-Bis[N,N′-(3-tolyl)amino]-3,3′-dimethylbiphenyl) or mCP, etc. Further, as described above, the electron blocking layer (EBL) may contain the compound according to an embodiment of the disclosure.

The hole transport region (HTR) may have a thickness of about 100 Å to about 10000 Å, for example, about 100 Å to about 5000 Å. For example, the hole injection layer (HIL) may have a thickness of about 30 Å to about 1000 Å, and the hole transport layer (HTL) may have a thickness of about 30 Å to 1000 Å. For example, the electron blocking layer (EBL) may have a thickness of about 10 Å to about 1000 Å. When the hole transport region (HTR), the hole injection layer (HIL), the hole transport layer (HTL), and the electron blocking layer (EBL) satisfy the foregoing thickness ranges, satisfactory hole transport characteristics are obtained without substantial increase in a driving voltage.

The hole transport region (HTR) may further contain charge generating materials for improving conductivity in addition to the foregoing materials. The charge generating materials may be uniformly or nonuniformly dispersed in the hole transport region (HTR). The charge generating materials may for example be a p-dopant. The p-dopant may be one of a quinone derivative, a metal oxide and a cyano group-containing compound, but is not limited thereto. For example, non-limiting examples of the p-dopant may include quinone derivatives such as tetracyanoquinodimethane (TCNQ) and 2,3,5,6-tetrafluoro-tetracyanoquinodimethane (F4-TCNQ); metal oxides such as tungsten oxide and molybdenum oxide; etc., but are not limited thereto.

As described above, the hole transport region (HTR) may further include at least one of the hole buffer layer and the electron blocking layer (EBL) in addition to the hole injection layer (HIL) and the hole transport layer (HTL). The hole buffer layer may compensate for a resonance distance according to the wavelengths of light emitted from the emission layer (EML), thereby increasing a light emission efficiency. As the material contained in the hole buffer layer, the material that can be contained in the hole transport region (HTR) may be used.

The emission layer (EML) is provided on the hole transport region (HTR). The emission layer (EML) may for example have a thickness greater than about 100 Å and less than or equal to 600 Å. The emission layer (EML) may have a single layer made of a single material, a single layer made of a plurality of different materials, or a multi-layered structure having a plurality of layers made of a plurality of different materials.

The emission layer (EML) may emit one of red light, green light, blue light, white light, yellow light, and cyan light. The emission layer (EML) may include a fluorescent material or a phosphorescent material.

According to an embodiment, the emission layer (EML) may be a fluorescence emission layer. For example, some of light emitted from the emission layer (EML) may be caused by the thermally activated delayed fluorescence (TADF). Specifically, the emission layer (EML) may include a light emissive component for the thermally activated delayed fluorescence emission, and the emission layer (EML) according to an embodiment may be an emission layer for the thermally activated delayed fluorescence emission that emits green or red light.

### FABRICATION EXAMPLES

Below, the disclosure will be described in more detail through specific embodiments and comparative examples. The following embodiments are merely examples to help understanding of the disclosure, and are not intended to limit the scope of the disclosure.

### Preparation Example 1

1.1. Synthesis of 10,10″-(5-bromo-2-chloro-1,3-phenylene)bis(10H-spiro[acridine-9,9′-xanthene])

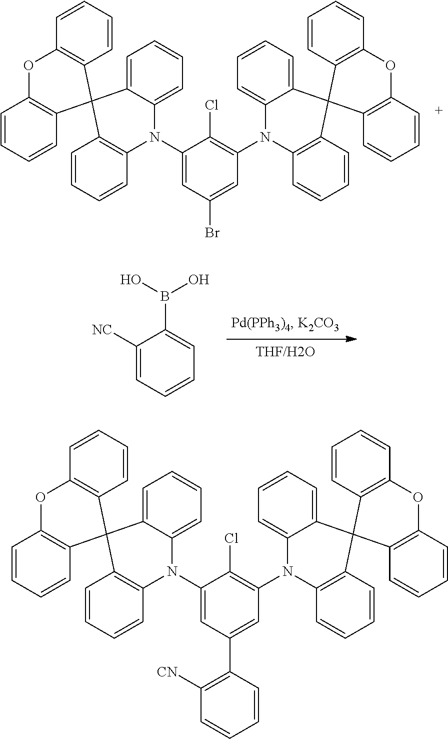

Under a stream of nitrogen, 5-bromo-2-chloro-1,3-difluorobenzene (40.0 g, 17 mmol), 10H-spiro[acridine-9,9′-xanthene](15.25 g, 43.9 mmol), and Cs2CO3 (27.6 g, 85 mmol) were agitated with 300 ml of DMF at 155° C. for 12 hours. When the reaction was completed, water was added to terminate the reaction and then 12.2 g (82%) of a target compound was obtained by recrystallization.

GC-Mass (theoretical value: 880.15 g/mol, and measured value: 882.25 g/mol)

1H-NMR: δ 7.31 (m, 4H), 7.19 to 7.14 (m, 20H), 7.01 to 6.95 (m, 8H), 6.82 (s, 2H)

### 1.2. Synthesis of 10,10″-(4-chloro-2′-isocyano-[1,1′-biphenyl]-3,5-diyl)bis(10H-spiro[acridine-9,9′-xanthene])

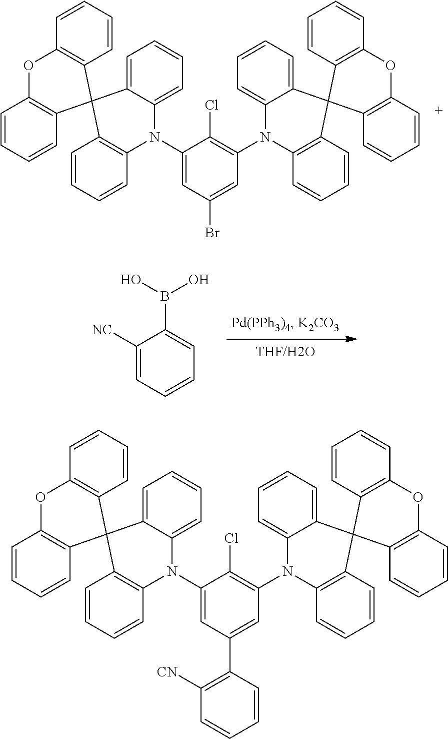

Under a stream of nitrogen, 1-1 (9.26 g, 10.5 mmol), (2-isocyanophenyl) boronic acid (1.7 g, 11.6 mmol), Pd(PPh₃)₄ (0.21 g), and K₂CO₃(3.62 g, 26.25 mmol) were added to 100 ml of THF/H₂O 100 ml and agitated at 155° C. for 12 hours. When the reaction was completed, water was added to terminate the reaction and then 7 g (74%) of a target compound was obtained by recrystallization.

GC-Mass (theoretical value: 903.27 g/mol, and measured value: 904.47 g/mol)

¹H-NMR: δ 7.77 (dd, 1H), 7.52 to 7.45 (m, 3H), 7.31 (m, 4H), 7.23 to 7.17 (m, 14H), 7.01 to 6.95 (m, 8H), 6.87 (s, 2H)

### Preparation Example 2

### Synthesis of 10,10″-(4-chloro-2′-isocyano-[1,1′-biphenyl]-3,5-diyl)bis(10H-spiro[acridine-9,9′-thioxanthene])

6.9 g of a target compound was obtained by performing the same process as [Preparation example 1] except that 10H-spiro[acridine-9,9′-thioxanthene] was used as a reactant.

GC-Mass (theoretical value: 935.22 g/mol, and measured value: 956.59 g/mol)

### Preparation Example 3

### Synthesis of 10′,10″ “′-(4-chloro-2′-isocyano-[1,1′-biphenyl]-3,5-diyl)bis(10-phenyl-10H,10′H-9,9′-spirobi[acridine])

7.2 g of a target compound was obtained by performing the same process as [Preparation example 1] except that 10-phenyl-10H, 10′H-9,9′-spirobi[acridine] was used as a reactant.

GC-Mass (theoretical value: 751.28 g/mol, and measured value: 752.36 g/mol)

### Preparation Example 4

### Synthesis of 10,10”-(4-chloro-2′-isocyano-[1,1′-biphenyl]-3,5-diyl)bis(10′,10′-dimethyl-10H, 10′H-spiro[acridine-9,9′-anthracene])

6.5 g of a target compound was obtained by performing the same process as [Preparation example 1] except that 10′,10′-dimethyl-10H,10′H-spiro[acridine-9,9′-anthracene] was used as a reactant.

GC-Mass (theoretical value: 1053.36 g/mol, and measured value: 1054.69 g/mol)

### Preparation Example 5

### Synthesis of 10,10″-(4-chloro-2′-isocyano-[1,1′-biphenyl]-3,5-diyl)bis(5′,5′-dimethyl-5′H, 10H-spiro[acridine-9,10′-dibenzo[b,e] siline])

7.3 g of a target compound was obtained by performing the same process as [Preparation example 1] except that 5′,5′-dimethyl-5′H, 10H-spiro[acridine-9,10′-dibenzo[b, e] siline] was used as a reactant.

GC-Mass (theoretical value: 987.32 g/mol, and measured value: 988.78 g/mol)

### Preparation Example 6

### Synthesis of 10.10″-(4-chloro-2′-isocyano-[1,l′-biphenyl]-3,5-diyl)bis(10H-spiro[acridine-9,7′-benzo[de]anthracene])

7.1 g of a target compound was obtained by performing the same process as [Preparation example 1] except that 10H-spiro[acridine-9,7′-benzo[de]anthracene] was used as a reactant.

GC-Mass (theoretical value: 971.31 g/mol, and measured value: 972.59 g/mol)

### Synthesis Example 1 Synthesis of Mat 1

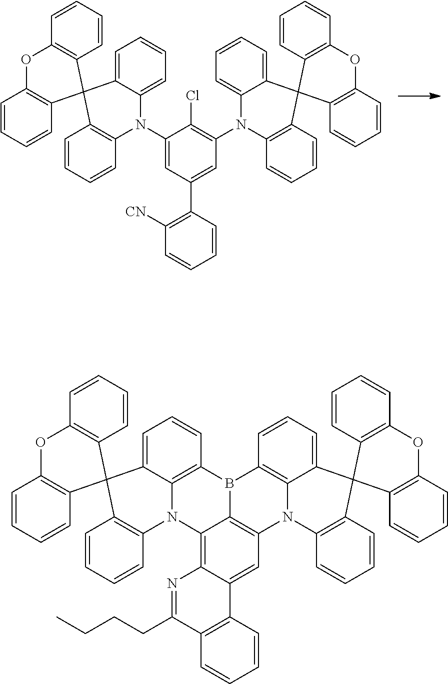

Under a stream of nitrogen, n-butyllithium (3.65 ml, 8.778 mmol) was slowly dropped to a 100 ml solution of 1-2 (7.2 g, 7.98 mmol), t-butylbenzene solution at 0° C., and then agitated for 30 minutes. After agitation, the mixed solution was heated to 60° C., and agitated for 2 hours. After the temperature was lowered to −40° C., tribromide (2 g, 7.98 mmol) was slowly dropped to the mixed solution, and the temperature of the mixed solution was raised up to room temperature. The mixed solution was agitated at room temperature for 30 minutes. After lowering the temperature to 0° C., N,N-diisopropylethylamine (1.65 g, 12.7 mmol) was slowly dropped to the mixed solution. The temperature was increased slowly up to the room temperature. The mixed solution was agitated at 120° C. for 5 hours. When the reaction is completed, the temperature is lowered to room temperature and the reaction is terminated with a sodium acetate dichloromethane solution. The mixed solution was extracted with M. C 500 mL, and washed with distilled water. The obtained organic layer was dried over anhydrous MgSO₄, distilled under reduced pressure, and purified by silica gel column chromatography to obtain 3.94 g (yield 53%) of the target compound.

GC-Mass (theoretical value: 933.35 g/mol, and measured value: 933.92 g/mol)

¹H-NMR: δ 7.92 (d, 1H), 7.83 (d, 1H), 7.68 to 7.61 (m, 3H), 7.31 (3, 4H), 7.19 to 7.17 (m, 16H), 7.01 (m, 8H), 6.60 (s, 1H), 2.77 (t, 2H), 1.62 (t, 2H), 1.33 (t, 1H), and 1.60 (t, 3H)

### Synthesis Example 2 Synthesis of Mat 2

3.65 g of a target compound was obtained by performing the same process as [Synthesis example 1] except that [Preparation example 2] was used as a reactant. HRMS [M]+: 967.04

### Synthesis Example 3 Synthesis of Mat 3

3.8 g of a target compound was obtained by performing the same process as [Synthesis example 1] except that [Preparation example 3] was used as a reactant. HRMS [M]+: 1085.15

### Synthesis Example 4 Synthesis of Mat 4

3.32 g of a target compound was obtained by performing the same process as [Synthesis example 1] except that [Preparation example 4] was used as a reactant. HRMS [M]+: 987.08

### Synthesis Example 5 Synthesis of Mat 5

3.72 g of a target compound was obtained by performing the same process as [Synthesis example 1] except that [Preparation example 5] was used as a reactant. HRMS [M]+: 1019.23

### Synthesis Example 6 Synthesis of Mat 6

3.55 g of a target compound was obtained by performing the same process as [Synthesis example 1] except that [Preparation example 6] was used as a reactant. HRMS [M]+: 1003.04

### Synthesis Example 7 Synthesis of Mat 7

3.55 g of a target compound was obtained by performing the same process as [Synthesis example 1] except that tert-butyllithium was used as a reactant. HRMS [M]+: 967.04

### Synthesis Example 8 Synthesis of Mat 8

3.44 g of a target compound was obtained by performing the same process as [Synthesis example 2] except that tert-butyllithium was used as a reactant. HRMS [M]+: 967.04

### Synthesis Example 9 Synthesis of Mat 9

3.61 g of a target compound was obtained by performing the same process as [Synthesis example 3] except that tert-butyllithium was used as a reactant. HRMS [M]+: 1085.15

### [Synthesis Example 10] Synthesis of Mat 10

3.21 g of a target compound was obtained by performing the same process as [Synthesis example 4] except that tert-butyllithium was used as a reactant. HRMS [M]+: 987.08

### [Synthesis Example 11] Synthesis of Mat 11

3.62 g of a target compound was obtained by performing the same process as [Synthesis example 5] except that tert-butyllithium was used as a reactant. HRMS [M]+: 1019.23

### [Synthesis Example 12] Synthesis of Mat 12

3.78 g of a target compound was obtained by performing the same process as [Synthesis example 6] except that tert-butyllithium was used as a reactant. HRMS [M]+: 1003.04

### [Synthesis Example 13] Synthesis of Mat 13

3.46 g of a target compound was obtained by performing the same process as [Synthesis example 1] except that phenyllithium was used as a reactant. HRMS [M]+: 954.91

### [Synthesis Example 14] Synthesis of Mat 14

3.53 g of a target compound was obtained by performing the same process as [Synthesis example 2] except that phenyllithium was used as a reactant. HRMS [M]+: 987.03

### [Synthesis Example 15] Synthesis of Mat 15

3.75 g of a target compound was obtained by performing the same process as [Synthesis example 3] except that phenyllithium was used as a reactant. HRMS [M]+: 1105.14

### [Synthesis Example 16] Synthesis of Mat 16

3.29 g of a target compound was obtained by performing the same process as [Synthesis example 4] except that phenyllithium was used as a reactant. HRMS [M]+: 1007.07

### [Synthesis Example 17] Synthesis of Mat 17

3.68 g of a target compound was obtained by performing the same process as [Synthesis example 5] except that phenyllithium was used as a reactant. [M]+: 1039.22

### [Synthesis Example 18] Synthesis of Mat 18

3.48 g of a target compound was obtained by performing the same process as [Synthesis example 6] except that phenyllithium was used as a reactant. HRMS [M]+: 1023.03

### [Embodiments 1 to 12] Fabrication of Green Organic EL Device

The compound synthesized in the Synthesis examples was subjected to high purity sublimation purification by a typically known method, and then green organic EL device was prepared by the following process.

First, a glass substrate coated with indium tin oxide (ITO) as a thin film having a thickness of 1500 Å was washed distilled water. After washed with distilled water, the glass substrate was subjected to ultrasonic cleaning with isopropyl alcohol, acetone, ethanol or the like solvent, dried, transferred to an ultraviolet (UV) ozone cleaner (Power Sonic 405, Hwashin Tech), cleaned using UV for 5 minutes, and transferred to a vacuum evaporator.

A hole injection layer was formed having a thickness of 80 nm with DS-205 (Doosan Electronics CO., LTD.) on the transparent ITO electrode prepared as above, and a hole transport layer was formed having a thickness of 30 nm with a-NPB(N,N′-Di(1-naphthyl)-N,N′-diphenyl-(1,1′-biphenyl)-4,4′-diamine) on the hole injection layer by vacuum deposition.

On the hole transport layer, an emission layer having a thickness of 30 nm was formed by using the compounds prepared by the Synthesis examples 1 to 18 as the green dopant materials and a common host of DS-H522 and DS-TD-002 as green light-emitting host materials. In this case, the same doping ratio (DS-H522: DS-TD-002: Synthesis examples 1 to 18=75%:20%:5%) was applied to the emission layer.

On the emission layer, an electron transport layer was formed having a thickness of 30 nm with an electron transport material of TPBi(2,2′,2″-(1,3,5-Benzinetriyl)-tris(1-phenyl-1-H-benzimidazole)). Then, an electron injection layer was formed having a thickness of 1 nm with LiF, and a cathode was formed having a thickness of 200 nm with Al, thereby fabricating the device.

### Comparative Example

The organic electroluminescence device was fabricated by the same method as the foregoing fabrication example of the device except that Alq3, a C-545T and Comparative example 1 represented as the green light-emitting material were used, and the evaluation results of the fabricated device are tabulated in the following Table 1.

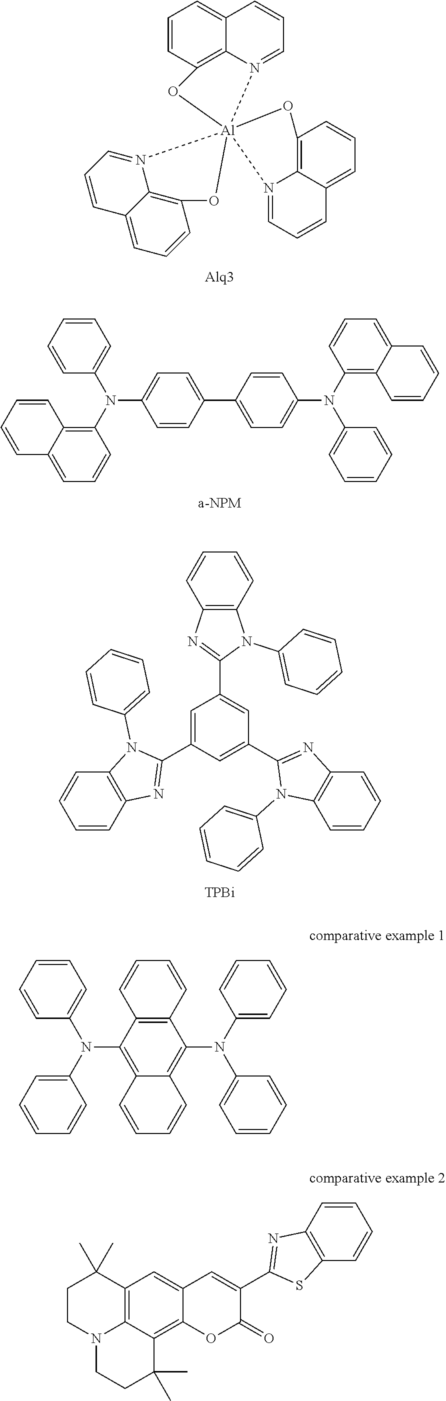

### Evaluation Example

Regarding the organic EL devices fabricated in Embodiments 1 to 18 and Comparative examples 1, 2 and 3, a driving voltage, a current efficiency, and an electroluminescence peak were measured at a current density of 10 mA/cm², and the results were tabulated in the following Table 1.

TABLE 1

| | | Driving | | Current |
|---|---|---|---|---|
| | Green | voltage | EL peak | efficiency |
| Samples | dopant | (V) | (nm) | (cd/A) |
| Embodiment 1 | Mat1 | 5.88 | 531 | 21.3 |
| Embodiment 2 | Mat3 | 5.19 | 537 | 23.1 |
| Embodiment 3 | Mat4 | 5.04 | 535 | 25.1 |
| Embodiment 4 | Mat7 | 5.7 | 536 | 21.4 |
| Embodiment 5 | Mat9 | 5.72 | 538 | 24.5 |
| Embodiment 6 | Mat10 | 5.22 | 531 | 21.3 |
| Embodiment 7 | Mat12 | 5.01 | 537 | 23.1 |
| Embodiment 8 | Mat13 | 5.18 | 535 | 25.1 |
| Embodiment 9 | Mat15 | 5.06 | 536 | 21.4 |
| Embodiment 10 | Mat16 | 5.88 | 538 | 26.7 |
| Embodiment 11 | Mat17 | 5.19 | 537 | 26.9 |
| Embodiment 12 | Mat18 | 5.04 | 541 | 26.3 |
| Comparative | Comparative | 6.52 | 515 | 14.9 |
| example 1 | example 1 | | | |
| Comparative | C-545T | 5.90 | 518 | 15.5 |
| example 2 | | | | |
| Comparative | Alq3 | 6.14 | 525 | 12.8 |
| example 3 | | | | |

As shown in Table 1, it was appreciated that the organic electroluminescence devices fabricated in the Embodiments 1 to 13 had a rigid chemical structure and a structure suitable for forming excitons in the emission layer and were thus superior to the organic electroluminescence devices fabricated in the Comparative examples 1, 2, and 3 in terms of the driving voltage, the electroluminescence peak, and the current efficiency.

1. A compound represented by the following Chemical formula 1: 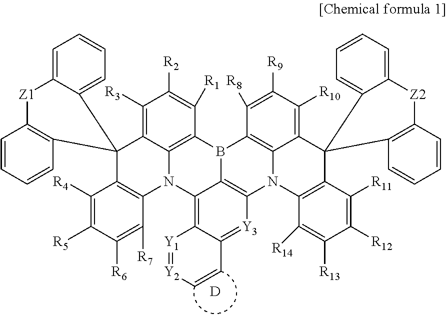
where, in Chemical formula 1,
R₁ to R₁₄ are each independently selected from a group consisting of a C₁ to C₃₀ alkyl group, a C₃ to C₃₀ cycloalkyl group, a C₁ to C₆₀ alkoxy group, a C₁ to C₁₀ thioalkoxy group, a carbonyl group, a carboxyl group, a nitro group, a cyano group, an amine group, a C₆ to C₃₀ arylamine group, a C₃ to C₃₀ heteroaryl group, a C₅ to C₆₀ monocyclic aryl group, a C₆ to C₆₀ condensed ring aryl group, a C₆ to C₆₀ aryloxy group, a C₅ to C₆₀ monocyclic heteroaryl group, and a C₅ to C₆₀ condensed ring heteroaryl group, and are bonded to an adjacent group to form a condensed ring,
Y₁ to Y₃ are each be independently selected from a group consisting of N or C(R₁₅)(R₁₆), at least one of which is N,
R₁₅ and R₁₆ are each independently selected from a group consisting of hydrogen, a C₁ to C₁₀ alkyl group, a C₃ to C₁₀ cycloalkyl group, a C₁ to C₁₀ alkoxy group, a halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₅ and R₁₆ are bonded to each other or bonded to an adjacent group to form a condensed ring,
Z₁ and Z₂ are each independently selected from a group consisting of C(R₁₇)(R₁₈), Si(R₁₇)(R₁₈), N(R₁₇), O or S,
R₁₇ and R₁₈ are each independently selected from a group consisting of hydrogen, a C₁ to C₁₀ alkyl group, a C₃ to C₁₀ cycloalkyl group, a C₁ to C₁₀ alkoxy group, halogen group, a cyano group, a nitro group, a hydroxyl group, a C₁ to C₁₀ silyl group, amino group, a C₆ to C₃₀ arylamino group, a C₃ to C₃₀ hetero arylamino group, a C₆ to C₃₀ aryl group, and a C₃ to C₃₀ heteroaryl group, in which R₁₇ and R₁₈ are bonded to each other or are bonded to an adjacent group to form a condensed ring,
a ring D is a group fused to a 6-membered ring structure containing Y₁ and Y₂, and is selected from a group consisting of a C₆-C₆₀ monocyclic aryl group, a C₆-C₆₀ condensed ring aryl group, a C₆-C₆₀ aryloxy group, a C₅ to C₆₀ monocyclic heteroaryl group, and a C₅ to C₆₀ condensed ring heteroaryl group, and
the alkyl group, the cycloalkyl group, the alkoxy group, the thioalkoxy group, the arylamine group, the heteroaryl group, the monocyclic aryl group, the condensed ring aryl group, the aryloxy group, the monocyclic heteroaryl group or the fused heteroaryl group are unsubstituted or substituted with one or more substituents each independently selected from a group consisting of heavy hydrogen, halogen, a cyano group, a nitro group, a C₁ to C₄₀ alkyl group, a C₂ to C₄₀ alkenyl group, a C₂ to C₄₀ alkynyl group, a C₆ to C₆₀ aryl group, a heteroaryl group having 5 to 60 nuclear atoms, a C₆ to C₆₀ aryloxy group, a C₁ to C₄₀ alkyloxy group, a C₆ to C₆₀ arylamine group, a C₃ to C₄₀ cycloalkyl group, a heterocycloalkyl group having 3 to 40 nuclear atoms, a C₁ to C₄₀ alkylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylsilyl group, which are the same as or different from each other when substituted with a plurality of substituents.

2. The compound of claim 1, wherein the ring D is a compound represented by the following Chemical formula 2 or Chemical formula 3: 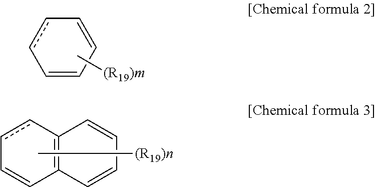
where, in the Chemical formulae 2 to 3,
the dotted line means a part that is fused;
m is an integer ranging from 0 to 4;
n is an integer ranging from 0 to 6;
R₁₉ is selected from a group consisting of hydrogen, heavy hydrogen, halogen, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₃ to C₄₀ alkylsilyl group, a C₆ to C₆₀ arylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylamine group, which are the same as or different from each other when the R₁₃ is present in plural number; and
the alkyl group, alkenyl group, alkynyl group, aryl group, heteroaryl group, aryloxy group, alkyloxy group, cycloalkyl group, heterocycloalkyl group, arylamine group, alkylsilyl group, alkyl boron group, aryl boron group, arylphosphanyl group, mono or diarylphosphinyl group, and arylsilyl group of the R₁₉ are unsubstituted or substituted with one or more substituents each independently selected from a group consisting of heavy hydrogen, halogen, a cyano group, a nitro group, a C₁ to C₄₀ alkyl group, a C₂ to C₄₀ alkenyl group, a C₂ to C₄₀ alkynyl group, a C₆ to C₆₀ aryl group, a heteroaryl group having 5 to 60 nuclear atoms, a C₆ to C₆₀ aryloxy group, a C₁ to C₄₀ alkyloxy group, a C₆ to C₆₀ arylamine group, a C₃ to C₄₀ cycloalkyl group, a heterocycloalkyl group having 3 to 40 nuclear atoms, a C₁ to C₄₀ alkylsilyl group, a C₁ to C₄₀ alkyl boron group, a C₆ to C₆₀ aryl boron group, a C₆ to C₆₀ arylphosphanyl group, a C₆ to C₆₀ mono or diarylphosphinyl group, and a C₆ to C₆₀ arylsilyl group, which are the same as or different from each other when substituted with a plurality of substituents.

3. The compound of claim 1, wherein the compound is selected from a group consisting of the following compounds:

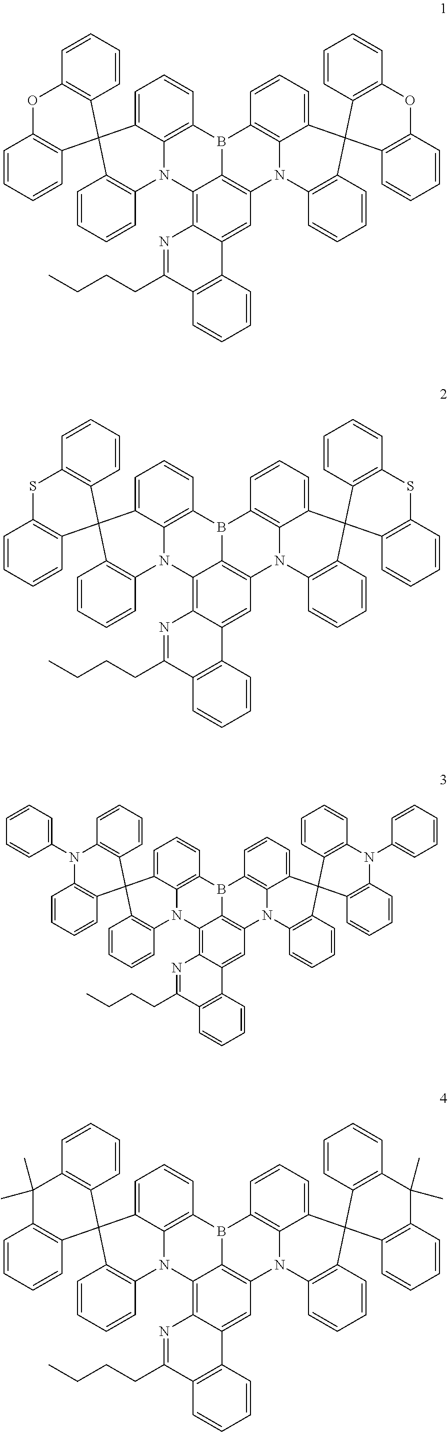

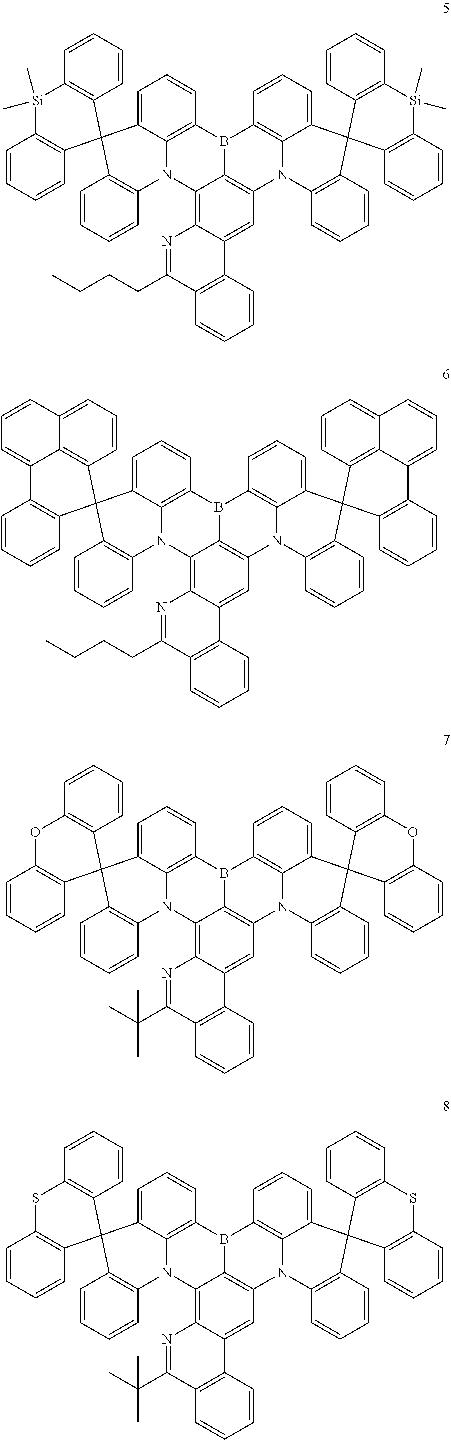

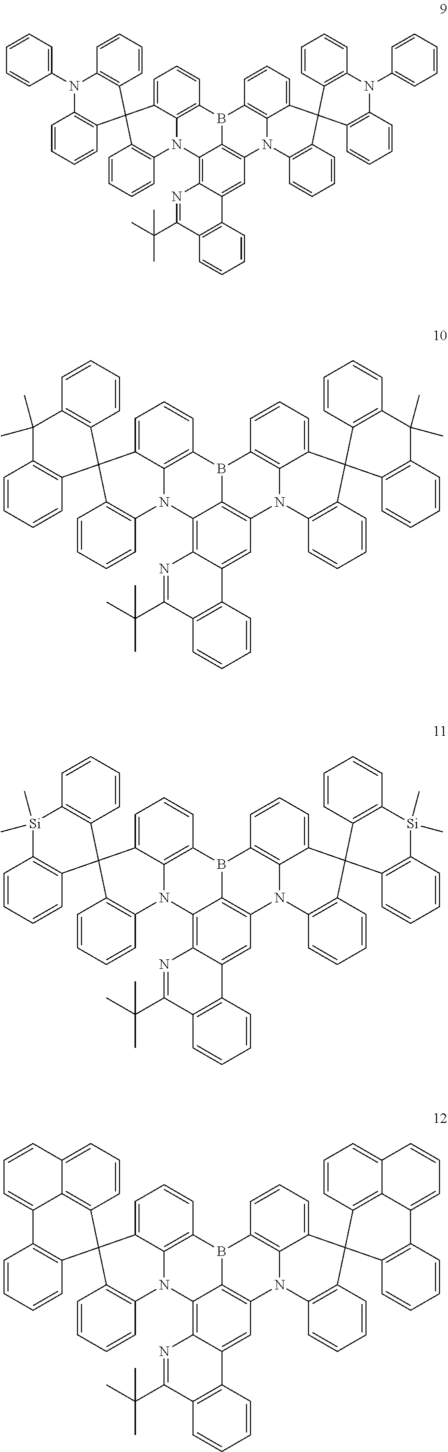

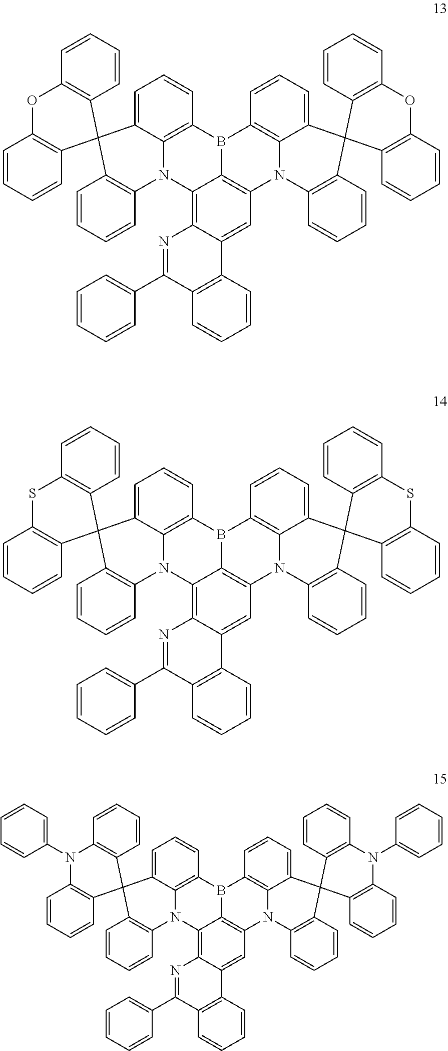 [SMILES: c1ccc(-c2nc3c4c5c(cc3c3ccccc23)N2c3ccccc3C3(c6ccccc6Oc6ccccc63)c3cccc(c32)B5c2cccc3c2N4c2ccccc2C32c3ccccc3Oc3ccccc32)cc1 ; c1ccc(-c2nc3c4c5c(cc3c3ccccc23)N2c3ccccc3C3(c6ccccc6Sc6ccccc63)c3cccc(c32)B5c2cccc3c2N4c2ccccc2C32c3ccccc3Sc3ccccc32)cc1 ; c1ccc(-c2nc3c4c5c(cc3c3ccccc23)N2c3ccccc3C3(c6ccccc6N(c6ccccc6)c6ccccc63)c3cccc(c32)B5c2cccc3c2N4c2ccccc2C32c3ccccc3N(c3ccccc3)c3ccccc32)cc1]

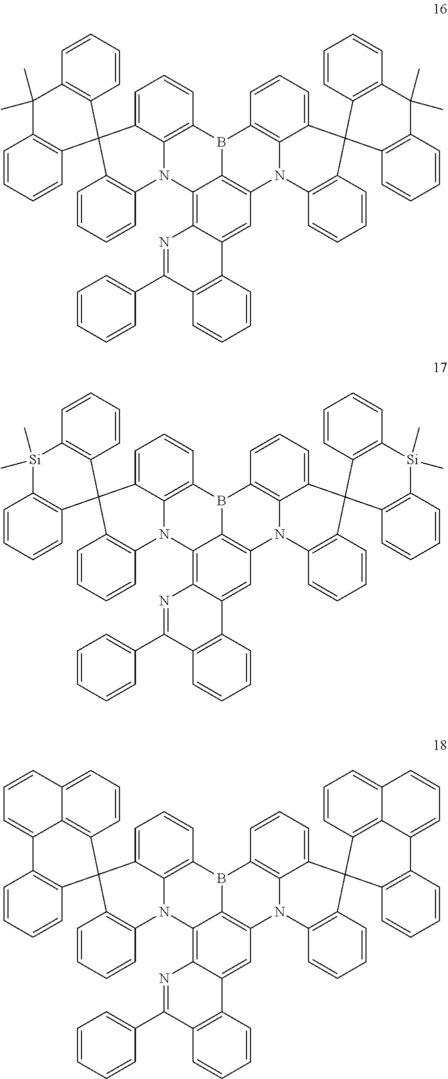

4. An organic electroluminescence device comprising:
a first electrode;
a hole transport region disposed on the first electrode;
an emission layer disposed on the hole transport region;
an electron transport region disposed on the emission layer; and
a second electrode disposed on the electron transport region,
wherein the emission layer contains the compound represented by the Chemical formula 1 of claim 1.

5. The organic electroluminescence device of claim 4, wherein the emission layer emits delayed fluorescence.

6. The organic electroluminescence device of claim 4, wherein the emission layer comprises a delayed fluorescence the emission layer comprising a host and a dopant, and the dopant is the compound.

7. The organic electroluminescence device of claim 4, wherein the emission layer is a thermally activated delayed fluorescence emission layer that emits blue light.
